(19) United States
(12) Patent Application Publication
(10) Pub. No.: US 2009/0007841 A1
(43) Pub. Date: Jan. 8, 2009

(54) VAPOR-PHASE GROWING APPARATUS AND VAPOR-PHASE GROWING METHOD

(76) Inventors: Hironobu Hirata, Shizuoka (JP); Hideki Arai, Shizuoka (JP)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 12/166,737

(22) Filed: Jul. 2, 2008

(30) Foreign Application Priority Data
Jul. 4, 2007 (JP) 2007-176527

(51) Int. Cl. C30B 23/00

(52) U.S. Cl. 117/84; 118/728

(57) ABSTRACT

A vapor-phase growing apparatus and a vapor-phase growing method which reduce sticking of a wafer to a holder during vapor-phase growth are provided. In the vapor-phase growing apparatus, a holder arranged in a chamber includes a disk-like member having a recessed portion at the center of a holder or a ring-like member having a recessed portion at a center of a holder and having an opening in a bottom center of the holder. A first projecting portion is arranged on an inner circumference wall surface of the holder, and a second projecting portion is formed on a bottom surface of the recessed portion of the holder. In this manner, the holder can support a wafer with a small contact area. In vapor-phase growth, the wafer can be prevented from sticking to the holder.

### CROSS-REFERENCE TO RELATED APPLICATION

This application is based upon and claims the benefit of priority from prior Japanese Patent Application No. 2007-176527, filed on Jul. 4, 2007, the entire contents of which are incorporated herein by reference.

### FIELD OF THE INVENTION

The present invention relates to a vapor-phase growing apparatus and a vapor-phase growing method and, more particularly, a vapor-phase growing apparatus in which a substrate support table for placing a semiconductor substrate such as a silicon wafer is improved and a vapor-phase growing method using the apparatus.

### BACKGROUND OF THE INVENTION

In a high-performance semiconductor element such as an ultrahigh-speed bipolar, an ultrahigh-speed CMOS, or a power MOS, an epitaxial growing technique which can control an impurity concentration or a film thickness is indispensable to improve the performance of the element. In epitaxial growth which forms a monocrystalline film on a semiconductor substrate such as a silicon wafer, an atmospheric pressure chemical vapor-phase growing method is generally used. Depending on circumstances, a low-pressure chemical vapor-phase growing (LPCVD) method is used.

In these vapor-phase growing methods, a vapor-phase growing reaction furnace in which a semiconductor substrate such as a silicon wafer is held at an atmospheric pressure (0.1 MPa (760 Torr)) or a low pressure, a source gas containing a silicon source and a dopant such as a boron compound, a phosphorous compound, or an arsenic compound is supplied while heating and rotating the semiconductor substrate. On a surface of the heated semiconductor substrate, thermal decomposition reaction or hydrogen reduction reaction of the source gas is performed to form a vapor-phase growing film in which boron (B), phosphorous (P), or arsenic (As) is doped (see JP-A H09-194296 (KOKAI)).

An epitaxial growing technique is used in manufacturing of a semiconductor element which requires a relatively thick crystal film such as an IGBT (Insulated Gate Bipolar Transistor). In a simple MOS device or the like, a film thickness of several micrometers or less is merely necessary. In contrast to this, formation of a base layer or an element isolation layer of the IGBT or the ultrahigh-speed bipolar device requires a crystal layer having a film thickness ranging from several ten micrometers to hundred and several ten micrometers or more. A vapor-phase growing apparatus and a vapor-phase growing method which can improve the productivity of a thick crystal film having a thickness of several ten micrometers or more are desired.

### SUMMARY OF THE INVENTION

According to an aspect of the present invention, a vapor-phase growing apparatus includes: a chamber which forms a space for performing vapor-phase growth; a substrate support table arranged in the chamber; a gas supply unit which supplies a process gas to form a film by the vapor-phase growth into the chamber; and a gas discharge unit which discharges the process gas after film formation from the chamber, in which the substrate support table includes a disk-like member having a recessed portion formed at a center thereof or a ring-like member formed by forming a recessed portion at the center of the substrate support table and forming an opening at a bottom center of the substrate support table, a first projecting portion formed on an inner circumference wall surface of the substrate support table to project from the inner circumference wall surface to the inside, and a second projecting portion formed upwardly from a bottom surface of the recessed portion of the substrate support table.

According to an aspect of the present invention, a vapor-phase growing method using a vapor-phase growing apparatus including: a chamber which forms a space for performing vapor-phase growth; a substrate support table arranged in the chamber; a gas supply unit which supplies a process gas to form a film by the vapor-phase growth into the chamber; and a gas discharge unit which discharges the process gas after film formation from the chamber, in which the substrate support table is constituted by a disk-like member having a recessed portion formed at a center thereof or a ring-like member formed by forming a recessed portion at the center of the substrate support table and forming an opening at a bottom center of the substrate support table, a first projecting portion formed on an inner circumference wall surface of the substrate support table to project from the inner circumference wall surface to the inside, and a second projecting portion formed upwardly from a bottom surface of the recessed portion of the substrate support table, includes: placing a substrate on the substrate support table, supplying the process gas from the gas supply unit, and forming a vapor-phase growing film on the substrate.

According to the present invention, an area in which a crystal film formed on a side surface portion or a rear surface portion of the semiconductor substrate in vapor-phase growth and a crystal film formed on the substrate support table on which the semiconductor substrate is placed can be reduced. As a result, a degree of sticking of the semiconductor substrate in the vapor-phase growth to the substrate support table can be reduced, and the productivity of the crystal film can be improved.

### BRIEF DESCRIPTION OF THE DRAWINGS

FIG. 1 is a conceptual sectional view of a vapor-phase growing apparatus according to an embodiment 1 of the present invention.

FIG. 2 is a conceptual sectional view of a holder and a wafer placed thereon in the embodiment 1 of the present invention.

FIG. 3 is an upper view of the holder according to the embodiment 1 of the present invention.

FIG. 4 is a conceptual sectional view for explaining a shape of the holder according to the embodiment 1 of the present invention.

FIG. 5 is a conceptual sectional view for explaining an operation according to the embodiment 1.

FIG. 6 is an upper view of a holder according to another aspect of the embodiment 1 of the present invention.

FIG. 7 is a conceptual sectional view of the holder and a wafer placed thereon according to another aspect of the embodiment 1 of the present invention.

FIG. 8 is an upper view of the holder shown in FIG. 7.

FIG. 9 is a conceptual sectional view of another aspect of the holder according to the embodiment 1 of the present invention and a wafer placed on the holder.

FIG. 10 is an upper view of the holder shown in FIG. 9.

FIGS. 11A to 11E are perspective views showing shapes of second projecting portions arranged on the holder according to the embodiment 1 of the present invention.

FIG. 12 is a conceptual sectional view of a holder according to an embodiment 2 of the present invention.

FIG. 13 is a conceptual sectional view showing an example of a conventional vapor-phase growing apparatus.

FIG. 14 is a conceptual sectional view showing a problem of the conventional vapor-phase growing apparatus shown in FIG. 13.

FIG. 15 is a conceptual sectional view showing a problem of a conventional vapor-phase growing apparatus.

### DETAILED DESCRIPTION OF THE EMBODIMENTS

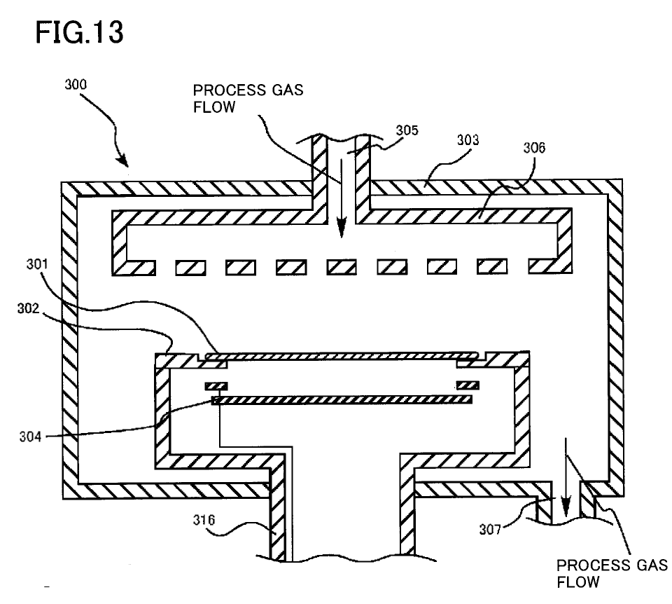

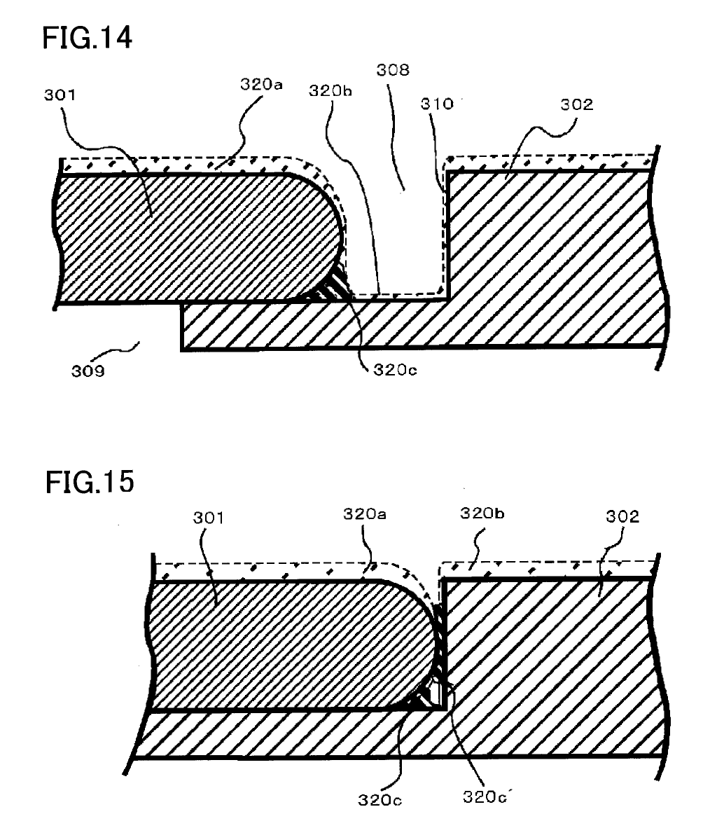

A conventional vapor-phase growing apparatus and a problem posed when vapor-phase growth is performed by using the conventional vapor-phase growing apparatus will be described first. FIG. 13 is a conceptual sectional view showing an example of the conventional vapor-phase growing apparatus. FIG. 14 is a conceptual sectional view showing a manner and a problem when vapor-phase growth is performed by the conventional vapor-phase growing apparatus. Furthermore, FIG. 15 is a conceptual sectional view showing a manner and a problem when vapor-phase growth is performed in a state in which a side surface portion of a substrate is in contact with an inner circumference wall surface of a substrate support table.

As shown in FIG. 13, a substrate support table 302 is attached to an upper portion of a rotating barrel 316 connected to a rotating mechanism (not shown) arranged outside a chamber 303. The rotating barrel 316 rotates about a center line orthogonal to a semiconductor substrate 301. With this rotation, the semiconductor substrate 301 placed on the substrate support table 302 rotates.

The substrate support table 302, for example, as shown in FIG. 14, includes a ring-like member having a recessed portion 308 and having a penetrating opening 309 formed at the center of the recessed portion 308 to have a diameter smaller than the inner diameter of the recessed portion 308. The recessed portion 308 is formed in a predetermined depth, and the semiconductor substrate 301 is supported by the bottom surface of the recessed portion 308.

As shown in FIG. 13, a heater 304 arranged immediately under the support table 302 is designed to easily heat the semiconductor substrate 301 because the support table 302 has the opening. In this state, a process gas containing a source component of a crystal film is supplied from a gas supply unit 305 while rotating the semiconductor substrate 301.

A shower head 306 is arranged immediately under the gas supply unit 305. For this reason, the process gas can be uniformly supplied to the semiconductor substrate 301. A silicon crystal film is formed on a surface of the heated substrate 301 by thermal decomposition reaction or hydrogen reduction reaction. A remaining gas after the film formation of the crystal film is discharged from a gas discharge unit 307.

By using the conventional vapor-phase growing apparatus, when a crystal film having several ten micrometers or more required to manufacture an IGBT or a power MOS is to be formed, the semiconductor substrate 301 disadvantageously sticks to the substrate support table 302. On the semiconductor substrate 301 placed on the bottom surface of the recessed portion 308, as shown in FIG. 14, a crystal film 320a formed on a side surface portion to a lower surface portion of the semiconductor substrate 301 is brought into contact with a crystal film 320b formed on an upper surface of the substrate support table 302 to the bottom surface of the recessed portion 308, and, in particular, at an end of the semiconductor substrate 301, a relatively thick crystal film 320c (thickly hatched portion in FIG. 14) is formed. By the thick crystal film 320c, the semiconductor substrate 301 sticks to the support table 302. Therefore, the semiconductor substrate 301 is difficult to be removed from the support table 302.

In this case, growing rates of films on the surface of the semiconductor substrate 301, the bottom surface of the recessed portion 308, an inner circumference wall surface 310 of the substrate support table 302 have the following relationships. More specifically, the growing rates of the films on the surface of the semiconductor substrate 301 and the upper surface of the substrate support table 302 are high, and the growing rates of the films on the side surface portion of the semiconductor substrate 301, the inner circumference wall surface 310 of the substrate support table 302, and the bottom surface of the recessed portion 308 are low. However, since growth on a rear surface side end of the semiconductor substrate 301 and growth on the bottom surface of the recessed portion 308 are superposed on each other, as described above, the relatively thick crystal film 320c is formed on the rear surface end of the semiconductor substrate 301. The crystal film 320c is not only relatively thick but also gets into a deep portion of the rear surface of the semiconductor substrate 301 to cause the rear surface of the semiconductor substrate 301 and the recessed portion 308 to stick to each other.

When the semiconductor substrate 301 freely moves in a nearly horizontal direction in response to centrifugal force or the like generated by high-speed rotation of the substrate support table 302, as shown in FIG. 15, the inner circumference wall surface 310 (inner side surface of the upper portion of the substrate support table 302) of the substrate support table 302 is in contact with the side surface portion of the semiconductor substrate 301. In this state, when vapor-phase growth is performed, a relatively thick crystal film 320c′ is generated on a contact surface between the side surface portion of the semiconductor substrate 301 and the inner circumference wall surface 310 of the substrate support table 302. For this reason, not only sticking between the rear surface of the semiconductor substrate 301 and the recessed portion 308 but also sticking with the relatively thick crystal film 320c and the crystal film 320c′ occur on the rear surface portion and the side surface portion of the semiconductor substrate 301. The semiconductor substrate 301 is further difficult to be removed from the substrate support table 302.

In this manner, in the conventional vapor-phase growing apparatus, the rear surface portion and the side surface portion of the semiconductor substrate 301 and the substrate support table 302 stack to each other to deteriorate the productivity and operating efficiency of the vapor-phase growing apparatus. An embodiment of a vapor-phase growing apparatus and a vapor-phase growing method, according to the present invention, which solve the problem held by the conventional vapor-phase growing apparatus will be described below.

### First Embodiment 1

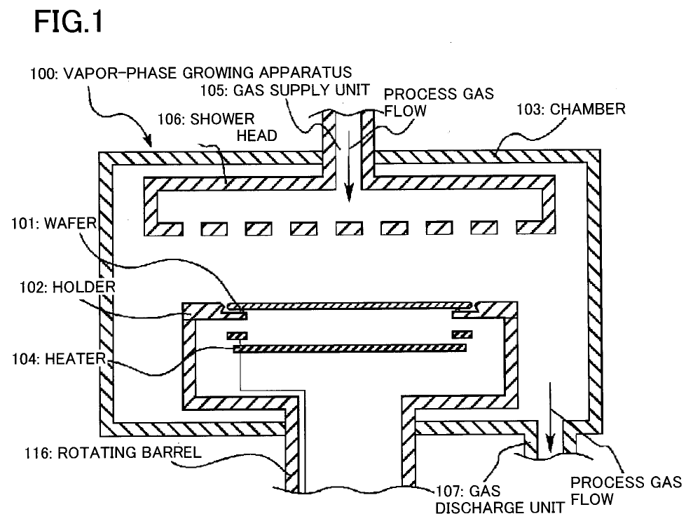

An embodiment 1 will be described below in detail with reference to the accompanying drawings. FIG. 1 is a conceptual diagram showing a vapor-phase growing apparatus according to the embodiment. A vapor-phase growing apparatus 100 shown in FIG. 1 has, for example, a holder 102 as a substrate support table for placing a wafer 101 serving as an example of a semiconductor substrate. The vapor-phase growing apparatus 100 includes a chamber 103 for storing the holder 102. The holder 102 is attached to the upper portion of a rotating barrel 116 connected to a rotating mechanism (not shown) arranged outside the chamber 103. The rotating barrel 116 rotates about a center line orthogonal to the wafer 101. Accordingly, the wafer 101 placed on the holder 102 rotates.

Immediately under the holder 102, a heater 104 to heat the wafer 101 placed on the holder 102 from the rear surface of the wafer 101 is arranged. On the upper portion of the chamber 103, a gas supply unit 105 which supplies a process gas containing a source component to generate a crystal film on the surface of the heated wafer 101 into the chamber 103 is arranged. The gas supply unit 105 is connected to a shower head 106 arranged above the holder 102 to face the surface of the wafer 101 to uniformly supply the process gas onto the surface of the wafer 101. On the lower portion of the chamber 103, a gas discharge unit 107 which discharges a remaining gas after the film formation of the crystal film out of the chamber 103 is arranged.

While the chamber 103 is set in an atmospheric pressure or held in a vacuum atmosphere having a predetermined degree of vacuum by a vacuum pump (not shown), the wafer 101 heats the heater 104. While the wafer 101 is rotated at a predetermined rotating speed by rotation of the holder 102, the process gas is supplied from the gas supply unit 105 into the chamber 103 through the shower head 106. Thermal decomposition reaction or hydrogen reduction reaction of the process gas is performed on the surface of the heated wafer 101 to form a crystal film on the surface of the wafer 101.

In FIG. 1, configurations except for the configurations necessary to explain the embodiment 1 are omitted, a reduced scale or the like is not matched with an actual reduced scale. This is also applied to the following drawings.

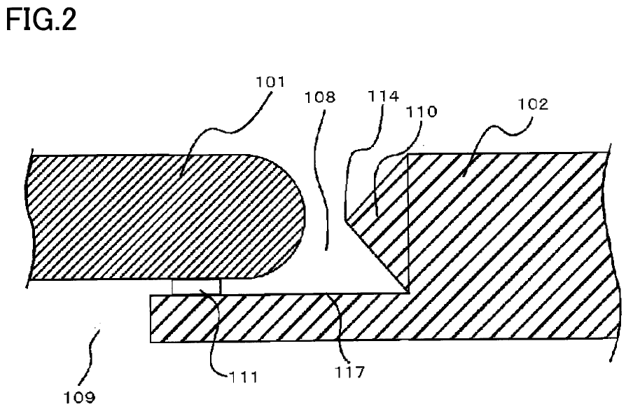

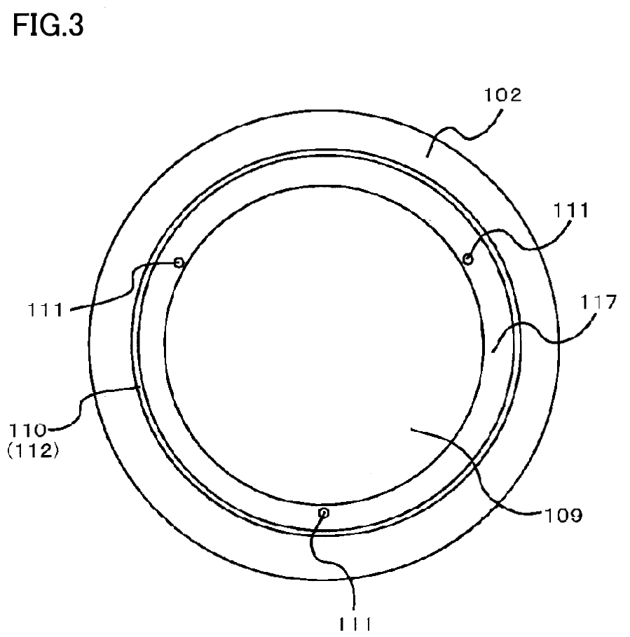

FIG. 2 is a conceptual sectional view obtained by enlarging the wafer 101 and the holder 102 according to the embodiment. FIG. 3 is an upper view of the holder 102 according to the embodiment. In the holder 102, a recessed portion 108 having a predetermined depth is formed in a center portion of a disk-like member, and an opening 109 having a diameter smaller than the inner diameter of the recessed portion 108 is formed in the bottom-surface center portion of the recessed portion 108. More specifically, the holder 102 is formed to have a ring-like shape. For this reason, the heater 104 arranged immediately under the holder 102 is designed to easily heat the wafer 101.

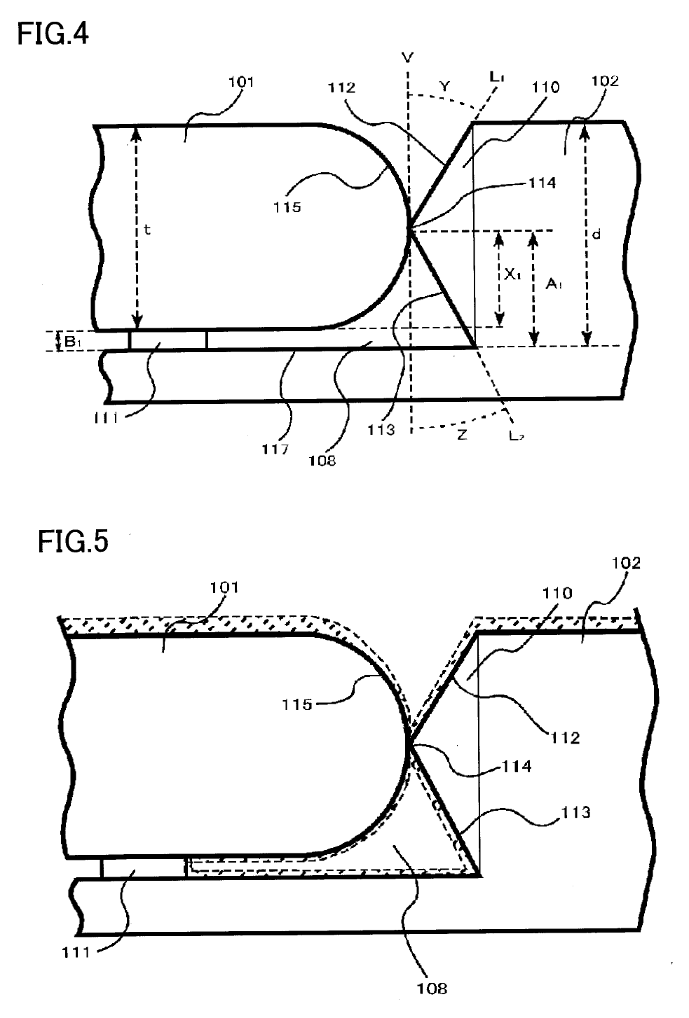

FIG. 4 is a conceptual diagram for explaining a shape of the holder 102 according to the embodiment. In this case, a first projecting portion 110 will be described below with reference to the drawing.

Since the recessed portion 108 is formed in the holder 102, an inner circumference wall surface having a predetermined height is formed. On the inner circumference wall surface, the first projecting portion 110 approximately arranged to entirely surround the circumference of the side surface portion 115 of the wafer 101. The shape of the section of the first projecting portion 110 is formed to have a triangular shape facing the inside of the holder 102. More specifically, the first projecting portion 110 is formed to project internally from the inner circumference wall surface of the holder 102.

In this case, an upper portion and a lower portion of two oblique lines of a triangle forming the first projecting portion 110 having a predetermined inclined angle are defined by a projecting-portion upper surface portion 112 and a projecting-portion lower surface portion 113, respectively. A common end of the projecting-portion upper surface portion 112 and the projecting-portion lower surface portion 113 near the center of the holder 102 is a distal end 114 of the first projecting portion 110 to face a side surface portion 115 of the wafer 101. The distal end 114 forms an annular edge line having a diameter slightly larger than the diameter of the wafer 101.

When the wafer 101 receives centrifugal force or the like generated by rotation of the holder 102, the wafer 101 freely moves in any direction almost parallel to the surface of the wafer 101. At this time, as shown in FIG. 4, the distal end 114 of the first projecting portion 110 is brought into contact with the side surface portion 115 of the wafer 101, so that free moving in a direction almost parallel to the wafer 101 can be constrained. In this case, the holder 102 is in contact with the side surface portion 115 of the wafer 101 at the distal end 114 of the first projecting portion 110. For this reason, the holder 102 supports the wafer 101 by a line contact having a small contact area.

FIG. 5 is a conceptual diagram showing a manner in which vapor-phase growth is performed in a state in which the wafer 101 is in contact with the first projecting portion 110. As shown in FIG. 5, the wafer 101 and the first projecting portion 110 are in contact with each other, a contact area therebetween is small. Therefore, even though the vapor-phase growth is performed in a state in which the distal end 114 is in contact with the side surface portion 115 of the wafer 101, a contact area between a crystal film formed on the surface of the wafer 101 and a crystal film formed on the holder 102 is also small. For this reason, a degree of sticking of the wafer 101 to the holder 102 on the side surface portion 115 can be reduced. Even though sticking occurs, since the contact area of the crystal films is small, the wafer 101 can be removed from the holder 102.

An arrangement position of the distal end 114 of the first projecting portion 110 will be described below. A height value of the position of the distal end 114 shown in FIG. 4 is defined as a distance X₁ obtained by subtracting a height B₁ of a second projecting portion 111 from a distance A₁ from a bottom surface 117 of the recessed portion 108 to the distal end 114 (distance from the lower end of the wafer 101 to a height position of a contact point between the wafer 101 and the distal end 114).

When the thickness of the wafer 101 is represented by t, the height X₁ of the position of the distal end 114 is preferably given by 0.3t≦X₁≦0.5t. More specifically, when a wafer having, for example, a diameter of 200 mm, the thickness t is 0.725 mm. For this reason, the X₁ ranges from 0.2175 mm (217.5 μm) to 0.3625 mm (362.5 μm). In this state, the side surface portion 115 of the wafer 101 is brought into contact with the distal end 114, the side surface portion of the wafer 101 can be stably supported. More specifically, when the distal end 114 is arranged at a height falling out of the range, even though the distal end 114 is brought into contact with the side surface portion 115 of the wafer 101 having a curved surface, free moving in a direction almost parallel to the surface of the wafer 101 cannot be constrained with respect to the surface.

When the side surface portion 115 of the wafer 101 is brought into contact with the holder 102 in a state in which the value of the height X₁ of the distal end 114 is larger than 0.5t, the wafer 101 gets into a space between the projecting-portion lower surface portion 113 and the bottom surface 117. When the value X₁ is larger than 0.5t and close to 1.0t, the distal end 114 is not contact with the side surface portion 115 of the wafer 101, and the side surface portion 115 of the wafer 101 is brought into contact with the projecting-portion lower surface portion 113.

In this state, when the wafer 101 is carried out upon completion of vapor-phase growth, the first projecting portion 110 itself is an obstacle and is difficult to be removed from the holder 102. When the wafer 101 is brought into area contact with the holder 102, the first projecting portion 110 is meaninglessly arranged on the inner circumference wall surface of the holder 102.

When the value of height X₁ of the distal end 114 is smaller than 0.3t, the distal end 114 may not be able to be in contact with the side surface portion 115 of the wafer 101 in a state in which the distal end 114 faces the side surface portion 115. More specifically, the wafer 101 runs on the projecting-portion upper surface portion 112, and the distal end 114 cannot support the side surface portion 115 of the wafer 101. At this time, vapor-phase growth cannot be performed in a state in which the wafer 101 is stably placed, and a high-quality crystal film cannot be formed. Furthermore, in the worst case, the wafer 101 is spun off by the rotating holder 102 to damage the wafer 101.

Furthermore, when the value X₁ is close to 0, the distal end 114 cannot be in contact with the side surface portion 115 of the wafer 101, the side surface portion 115 of the wafer 101 is brought into contact with the projecting-portion upper surface portion 112. When the wafer 101 and the holder 102 are brought into area contact with the each other, as in the case in which the value X₁ is excessively large, the first projecting portion 110 is meaninglessly arranged on the inner circumference wall surface of the holder 102.

Angles of inclination of the projecting-portion upper surface portion 112 and the projecting-portion lower surface portion 113 will be described below. For this explanation, a virtual straight line V passing through the distal end 114 serving as a contact point between the wafer 101 and the first projecting portion 110 and being vertical to the bottom surface 117 of the recessed portion 108 is set and shown in FIG. 4.

An angle of inclination Y formed by a straight line L₁ formed by the projecting-portion upper surface portion 112 and the straight line V is preferably given by 0°≦Y≦90°. An angle of inclination Z formed by a straight line L₂ formed by the projecting-portion lower surface portion 113 and the straight line V is preferably given by 0°<Z≦45°.

The first projecting portion 110 formed by the projecting-portion upper surface portion 112 and the projecting-portion lower surface portion 113 having the angles of inclination falling in the ranges supports the side surface portion 115 of the wafer 101 by a small contact area such as a line contact. For this reason, as shown in FIG. 5, even though vapor-phase growth is performed in a state in which the side surface portion 115 of the wafer 101 is brought into contact with the holder 102, a degree of sticking of the wafer 101 to the holder 102 can be reduced.

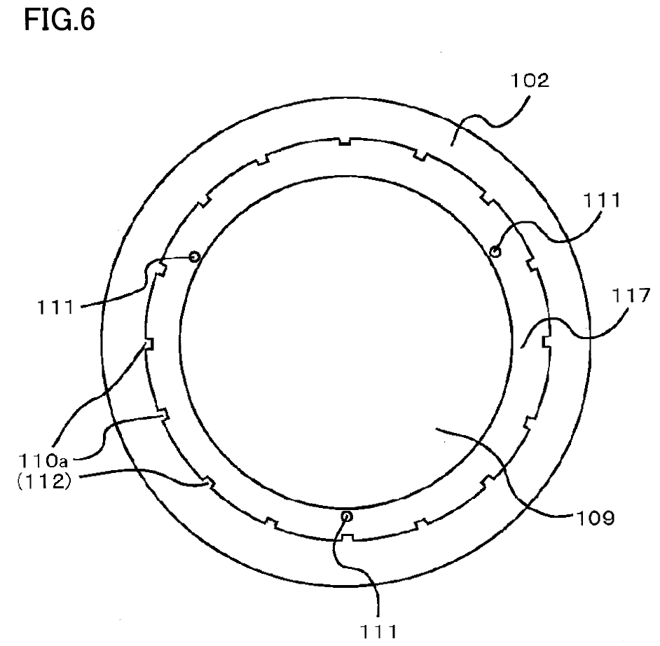

Furthermore, another aspect of the first projecting portion 110 will be described below. FIG. 6 is a conceptual diagram showing an example of another aspect of the holder 102 according to the embodiment from above. The first projecting portion 110 is preferably supported by a less contact area when the first projecting portion 110 supports the wafer 101 placed on the holder 102. For this reason, in order to further reduce a contact area between the first projecting portion 110 and the wafer 101, a plurality of first projecting portions 110a may be arranged at equal intervals as shown in FIG. 6.

The first projecting portion 110 in FIG. 3 has an annular shape, and can support the circular wafer 101 by a line contact having a predetermined region. However, the line contact regions of the plurality of first projecting portions 110a arranged at equal intervals on the inner circumference wall surface of the holder 102 shown here further decrease. In this manner, a degree of sticking between the side surface portion 115 of the wafer 101 and the holder 102 can be further reduced.

A second projecting portion will be described below. As shown in FIGS. 2 and 3, a second projecting portion 111 which supports the wafer 101 such that the second projecting portion 111 is brought into contact with the rear surface of the wafer 101 is formed on a bottom surface 117 of a recessed portion 108. The second projecting portion 111 is formed to have a cylindrical shape vertically arranged from the bottom surface 117 of the recessed portion 108, and a flatly formed top surface (upper surface of the cylinder) is brought into contact with the rear surface of the wafer 101.

As shown in FIG. 3, the plurality of second projecting portions 111 are arranged at positions arranged at almost equal intervals of the bottom surface 117 of the recessed portion 108. In this manner, the second projecting portions 111 can stably support the wafer 101. At this time, a diameter φ of the second projecting portion 111 preferably falls within the range of about 0.5 mm to 2 mm.

In comparison with the conventional vapor-phase growing apparatus, in the embodiment in which the second projecting portions 111 support the rear surface of the wafer 101, a contact area between the rear surface of the wafer 101 and the holder 102 is small. Therefore, a degree of sticking of the wafer 101 to the holder 102 can be reduced.

Even though the wafer 101 sticks to the holder 102 at a contact portion to the second projecting portion 111, a contact region between the crystal films is small. For this reason, the sticking is not strong. For this reason, the wafer 101 can be easily removed from the holder 102. The wafer 101 is not easily broken when the wafer 101 is removed from the holder 102.

Furthermore, when a surface of the wafer 101 or a portion of a relatively thin crystal film generated on the side surface portion 115 is scratched by sticking between the wafer 101 and the holder 102, in the subsequent operation step, the wafer 101 may be broken due to the scratch. However, in the embodiment, since sticking occurs on the rear surface of the wafer 101, in the subsequent operation steps, the risk of breaking the wafer 101 can be reduced.

In this case, although the three second projecting portions 111 are arranged at almost equal intervals on the bottom surface 117, the number of second projecting portions 111 is not limited to three, and three or more second projecting portions 111 may be used. When the number of arranged second projecting portions 111 is large, a friction coefficient between the wafer 101 and the holder 102 increases. In rotation of the holder 102, the wafer 101 can be suppressed from being freely moved in a nearly horizontal direction of the surface of the wafer 101.

When the number of arranged second projecting portions 111 is close to three, a contact region between the crystal films generated near the wafer 101 and the second projecting portion 111 is reduced, and a degree of sticking between the wafer 101 and the holder 102 can be reduced. The small contact area means that a portion which radiates heat from the wafer 101 to the holder 102 is small. For this reason, a region in which a temperature locally decreases in the plane of the wafer 101 is reduced to contribute to improvement of uniformity of film thicknesses of the crystal films to be formed.

In this case, as shown in FIG. 4, the height of the second projecting portion 111 is preferably ⅛ or more and ⅕ or less to a distance A₁ from a contact point between the side surface portion 115 of the wafer 101 and the distal end 114 of the first projecting portion 110 to the bottom surface 117 of the recessed portion 108. More specifically, when the height of the second projecting portion 111 falls within the range, even though a crystal film having a large film thickness and required in manufacturing a high-performance semiconductor element is generated, the crystal film generated on the bottom surface 117 of the recessed portion 108 reaches the rear surface of the wafer 101 to prevent the wafer 101 and the holder 102 from sticking to each other. More specifically, the second projecting portion 111 is preferably formed to have a height larger than the thickness of the crystal film formed on the wafer 101.

Even though the height of the second projecting portion 111 is equal to or larger than the thickness of the crystal film to be formed, it is not actually possible that the height is extremely large, i.e., equal to or larger than the thickness of a wafer to be used in general. When the second projecting portion 111 is excessively high, free moving in a nearly horizontal direction cannot be constrained by the first projecting portion 110. When the second projecting portion 111 having a height falling within the range is formed, a degree of sticking between the wafer 101 and the rear surface of the holder 102 can be reduced while generating a crystal film having a predetermined film thickness on the surface of the wafer 101.

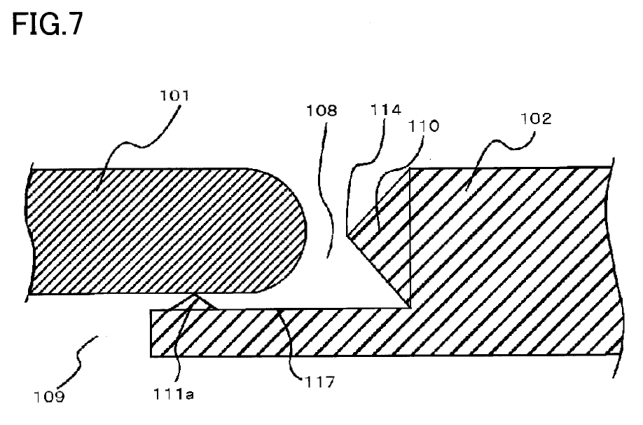

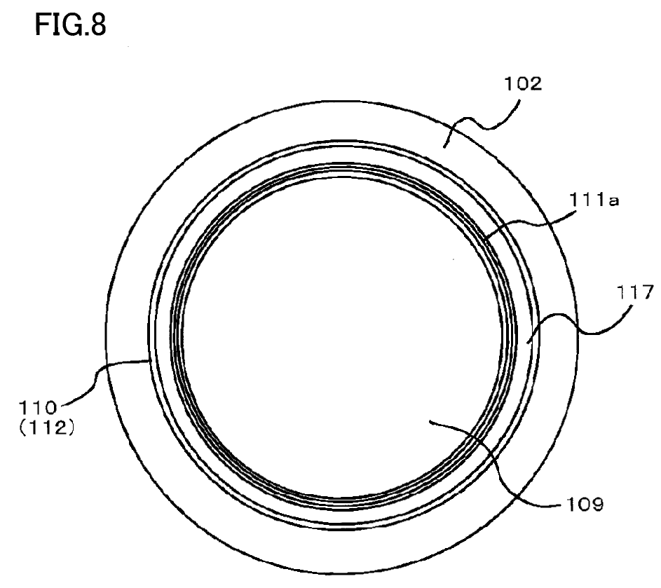

FIG. 7 is a conceptual sectional view of an example of another aspect of the holder 102 according to the embodiment and a wafer 101 placed on the holder 102. FIG. 8 is an upper view of the holder 102. As shown in FIG. 7, a section of a second projecting portion 111a formed on a bottom surface 117 of the recessed portion 108 is a triangular shape which is uprightly formed. The second projecting portion 111a supports the wafer 101 such that a top of the second projecting portion 111a is brought into contact with the rear surface of the wafer 101. As shown in FIG. 8, the second projecting portions 111a are formed on the bottom surface 117 of the recessed portion 108 in an annular ridge shape.

A contact area between the second projecting portion 111a of this aspect and the wafer 101 is smaller than that of the second projecting portion 111 having a cylindrical shape. For this reason, a region where sticking between the rear surface of the wafer 101 and the holder 102 in vapor-phase growth can be more reduced.

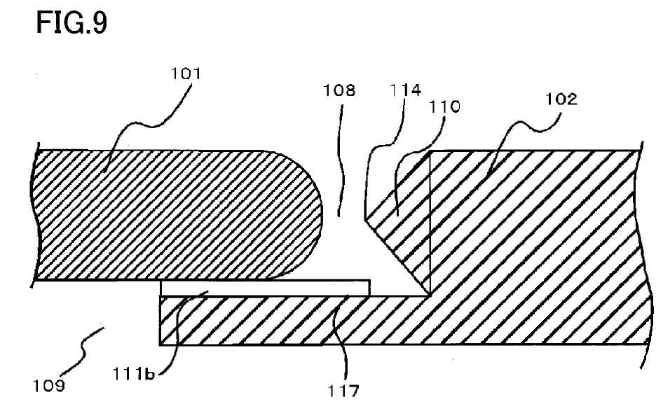

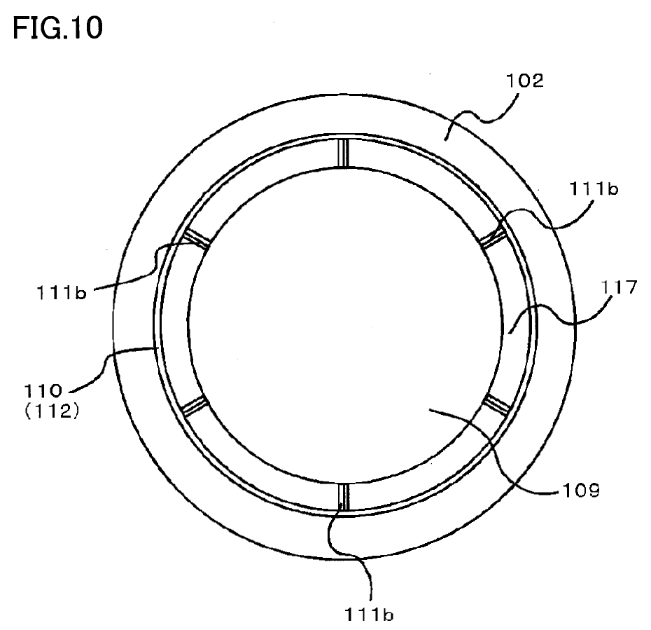

Furthermore, FIG. 9 is a conceptual sectional view of an example of another aspect of the holder 102 according to the embodiment and a wafer 101 placed on the holder 102. FIG. 10 is an upper view of the holder 102 shown in FIG. 9. As shown in FIG. 9, a second projecting portion 111b formed on a bottom surface 117 is formed such that one surface of a triangular prism is brought into contact with the bottom surface 117. As shown in FIG. 10, six second projecting portions 111b are arranged at almost equal intervals on the bottom surface 117 of the recessed portion 108. The second projecting portions 111b are radially arranged about the holder 102 to make it possible to stably support the wafer 101.

A contact area between the second projecting portion 111b according to the aspect and the wafer 101 can be smaller than that the second projecting portion 111 having a cylindrical shape, and a degree of sticking between the wafer 101 and the holder 102 in vapor-phase growth can be further reduced. In this aspect, six second projecting portions 111b are arranged. However, like the second projecting portion 111 having the cylindrical shape, three or more second projecting portions 111b may be arranged. Since a characteristic feature obtained when the number of arranged second projecting portions 111b is increased or decreased is the same as that described about the second projecting portion 111 having the cylindrical shape, a description thereof will be omitted.

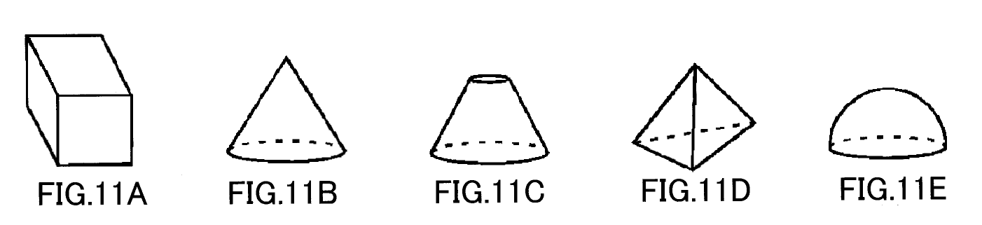

It is important that the number of second projecting portions 111 and the regions of the second projecting portions 111 are set such that the wafer 101 can be stably supported and that the second projecting portions 111 are formed in shape such that the second projecting portions 111 are not in area contact with the rear surface of the wafer 101 with a large area. For example, aspects having various shapes such as a quadratic prism shown in FIG. 11A, a conical shape shown in FIG. 11B, a circular truncated cone shown in FIG. 11C, a triangular pyramid shown in FIG. 11D, and a semisphere shown in FIG. 11E may be used. The second projecting portions having various shapes may be formed in a continuous annular shape like the second projecting portions 111a.

In a state in which the chamber 103 serving as a vapor-phase growing reaction furnace of the vapor-phase growing apparatus 100 is held in an atmospheric pressure or a vacuum atmosphere having a predetermined degree of vacuum, the wafer 101 is heated by the heater 104. While the wafer 101 is rotated at a predetermined rotating speed by rotation of the holder 102 rotated with rotation of the rotating barrel 116, the gas supply unit 105 supplies a process gas serving as a silicon source into the chamber 103 through the shower head 106.

A depth d of the recessed portion 108 is preferably equal to or smaller than a value obtained by adding the thickness t of the wafer 101 and a height B₁ of the second projecting portion 111. The process gas supplied onto the surface of the wafer 101 almost horizontally flows along the surface of the wafer 101. At this time, when the depth d of the recessed portion 108 is equal to or smaller than t+B₁, the inner circumference wall surface of the holder 102 does not disturb the flow of the process gas not to cause crosscurrent.

Thermal decomposition reaction or hydrogen reduction reaction of the process gas is performed on the surface of the wafer 101 heated by the heater 104 to form a crystal film on the surface of the wafer 101. At this time, even though, by the above operation, vapor-phase growth to form a crystal film having a large thickness is performed for a long period of time, the wafer 101 can be prevented from easily sticking to the holder 102.

### Embodiment 2

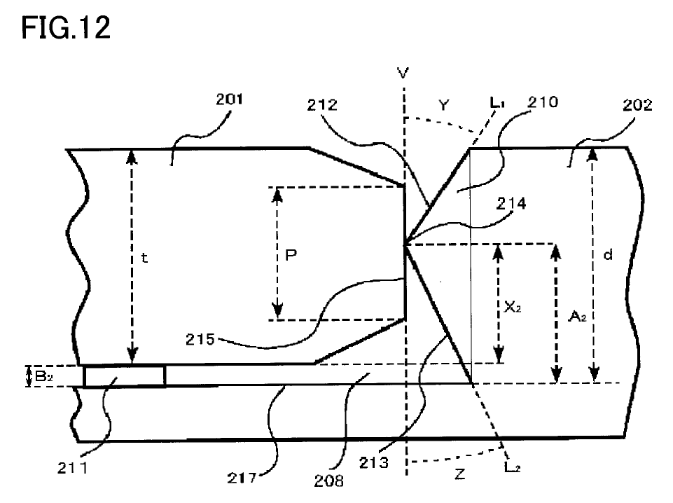

FIG. 12 is a conceptual sectional view shown to explain a shape of a holder 202 according to the embodiment.

A wafer 201 according to the embodiment is configured such that a side surface portion 215 has a plurality of inclined surfaces having predetermined angles with respect to a flat surface and the surface of the wafer 201. When the wafer 201 is placed on the holder 202, a side flat surface portion 215 serving as a side end of the wafer 201 is almost vertical to a surface of the wafer 201 and a bottom surface 217 of a recessed portion 208.

On the inner circumferential wall surface of the holder 202, a first projecting portion 210 is formed such that the first projecting portion 210 faces the flat side surface portion 215 of the wafer 201 and approximates to the side surface portion 215 to surround the entire circumference of the side surface portion 215. A shape of a section of the first projecting portion 210 is a triangular shape facing the inside of the holder 202. More specifically, the first projecting portion 210 is formed to project from the inner circumference wall surface of the holder 202 to the inside of the holder 202.

In this case, an upper portion and a lower portion of two oblique lines of a triangle forming the first projecting portion 210 having a predetermined inclined angle are defined by a projecting-portion upper surface portion 212 and a projecting-portion lower surface portion 213, respectively. A common end of the projecting-portion upper surface portion 212 and the projecting-portion lower surface portion 213 near the center of the holder 202 is a distal end portion 214 of the first projecting portion 210 to face a flat side surface portion 215 of the wafer 201. The distal end portion 214 forms an annular edge line having a diameter slightly larger than the diameter of the wafer 201.

When the wafer 201 receives centrifugal force or the like generated by rotation of the holder 102, the wafer 201 freely moves in any direction almost parallel to the surface of the wafer 201. At this time, the distal end portion 214 is brought into contact with the flat side surface portion 215 of the wafer 201, so that free moving in a direction almost parallel to the surface of the wafer 201 can be constrained. In this case, the holder 202 supports the side surface portion 215 of the wafer 201 by a line contact having a small contact area.

For this reason, even though the flat side surface portion 215 of the wafer 201 is in contact with the distal end portion 214 of the first projecting portion 210 in vapor-phase growth, a contact area between a crystal film formed on a surface of the wafer 201 and a crystal film formed on the holder 202 is small. For this reason, a degree of sticking between the wafer 201 and the holder 202 can be reduced. Even though the sticking occurs, since the contact region between the crystal films is small, the wafer 101 can be removed from the holder 202.

A position at which the distal end portion 214 of the first projecting portion 210 is to be arranged will be described below. A height value of the position of the distal end portion 214 shown in FIG. 12 is defined as a distance X₂ obtained by subtracting a height B₂ of a second projecting portion 211 from a distance A₂ from a bottom surface 217 of the recessed portion 208 to the distal end portion 214 (distance from the lower end of the wafer 201 to a height position of a contact point between the flat side surface portion 215 and the distal end portion 214).

The height X₂ of the position of the distal end portion 214 is preferably given by 0.3t≦X₂≦0.7t. More specifically, in this range, the distal end portion 214 can capture the flat side surface portion 215 of the wafer 201. More specifically, for example, a wafer has a diameter of 200 mm, the thickness t is 0.725 mm. For this reason, the X₂ ranges from 0.2175 mm (217.5 μm) to 0.5075 mm (507.5 μm). In this state, since the distal end portion 214 is in contact with the flat side surface portion 215 in a state of facing the side surface portion 215, the wafer 201 can be stably supported.

When a size of the flat side surface portion depends on a wafer used in vapor-phase growth, accordingly, the position of the distal end portion 214 maybe changed. More specifically, the flat side surface portion 215 of the wafer 201 and the distal end portion 214 may be arranged to face each other.

When the value of the height X₂ of the distal end portion 214 exceeds 0.7t, the distal end portion 214 may not be in contact with the flat side surface portion 215 in a state of facing the side surface portion 215. More specifically, the wafer 201 gets into the space between the projecting-portion lower surface portion 213 and the bottom surface 217. In this state, when the first projecting portion 210 is conveyed out upon completion of the vapor-phase growth, the first projecting portion 210 is not easily removed from the holder 202 due to the first projecting portion 210 itself. Therefore, the first projecting portion 210 is meaninglessly arranged on the inner circumference wall surface of the holder 202.

When the value of the height X₂ of the distal end portion 214 is smaller than 0.3t, the distal end portion 214 may not be in contact with the side surface portion 215 of the wafer 201 in a state of facing the side surface portion 215. More specifically, the wafer 201 runs on the projecting-portion upper surface portion 212, and the distal end portion 214 cannot support the wafer side surface portion 215 of the wafer 201. At this time, vapor-phase growth cannot be performed in a state in which the wafer 101 is stably placed, and a high-quality crystal film cannot be formed. Furthermore, in the worst case, the wafer 201 is spun off by the rotating holder 202 to damage the wafer 201.

Since the wafer 201 used in the embodiment has a flat surface on the side surface portion 215, a range of a height position of the distal end portion 214 formed on the first projecting portion 210 conforms to this regulation. Therefore, in the embodiment, a height of the second projecting portion 211 is preferably 1/11 or more and ⅕ or less of the height X₂ of the distal end portion 214. When the value of the height X₂ of the distal end portion 214 is close to 0.7t, a ratio of the height of the second projecting portion 211 to the height X₂ is small. when the height X₂ is close to 0.3t, a ratio of the height of the second projecting portion 211 to the height X₂ is large.

In other words, the height B₁ of the second projecting portion 111 described in the embodiment 1 may be substantially equal to the height B₂ of the second projecting portion 211 used in the embodiment 2. In this case, since a range of the position of the distal end portion 214 used to explain the height B₂ of the second projecting portion 211 is wider than the range of the distal end portion 114 according to the embodiment 1, a numerical value representing the height B₂ of the second projecting portion 211 is expressed as a relatively small value. More specifically, when the thickness of the crystal film actually generated on the wafer 201 is equal to that described in the embodiment 1, a degree of sticking between the rear surface of the wafer 201 and the holder 202 can be reduced when the height B₂ of the second projecting portion 211 is substantially equal to the height B₁ of the second projecting portion 111 according to the embodiment 1.

Since angles at which the projecting-portion upper surface portion 212 and the projecting-portion lower surface portion 213 of the first projecting portion 210 are formed, a position where the second projecting portion 201 is arranged on the bottom surface 217 of the recessed portion 208, and the like are the same as those described in the embodiment 1, a description thereof will be omitted. Since the various shapes illustrated in the embodiment 1 can be appropriately employed as the shape of the second projecting portion 211, a description thereof will be omitted.

As described above, according to the embodiments of the present invention, a contact area between a crystal film formed on a side surface portion or a rear surface portion of a semiconductor substrate in vapor-phase growth and a crystal film formed on a substrate support table on which the semiconductor substrate is placed can be reduced. As a result, a degree of sticking between the semiconductor substrate and the substrate support table in the vapor-phase growth can be reduced. Therefore, productivity and a yield in the vapor-phase growth can be improved.

The embodiments are described with reference to concrete examples. The present invention is not limited to the embodiments described above, and various modifications of the invention can be effected without departing from the spirit and scope of the invention.

The present invention describes an epitaxial growing apparatus as an example of a vapor-phase growing apparatus. However, the present invention is not limited to the epitaxial growing apparatus, and an apparatus to perform vapor-phase growth of a predetermined crystal film on a wafer surface may be used. For example, an apparatus or the like to grow a thin film such as a polysilicon film may be used.

Furthermore, descriptions of parts such as an apparatus configuration and a control method which are not directly necessary for the present invention are omitted. However, a necessary apparatus configuration and a necessary control method can be arbitrarily selected and used. In addition, all vapor-phase growing apparatuses and vapor-phase growing methods which include the elements of the present invention and which can be arbitrarily changed in design by a person skilled in the art are included in the spirit and scope of the present invention.

What is claimed is:

1. A vapor-phase growing apparatus comprising:
a chamber which forms a space for performing vapor-phase growth;
a substrate support table arranged in the chamber;
a gas supply unit which supplies a process gas to form a film by the vapor-phase growth into the chamber; and
a gas discharge unit which discharges the process gas after film formation from the chamber, wherein
the substrate support table is constituted by a disk-like member having a recessed portion formed at a center thereof or a ring-like member formed by forming a recessed portion at the center of the substrate support table and forming an opening at a bottom center of the substrate support table,
a first projecting portion formed on an inner circumference wall surface of the substrate support table to project from the inner circumference wall surface to the inside, and
a second projecting portion formed upwardly from a bottom surface of the recessed portion of the substrate support table.

2. The apparatus according to claim 1, wherein
the first projecting portion is annularly arranged along the inner circumference wall surface.

3. The apparatus according to claim 1, wherein
the plurality of first projecting portions are arranged at equal intervals on the inner circumference wall surface.

4. The apparatus according to claim 1, wherein
the first projecting portion has a triangular section.

5. The apparatus according to claim 2, wherein
the first projecting portion has a triangular section.

6. The apparatus according to claim 1, wherein
the second projecting portion has any one of a cylindrical shape, a prismatic shape, a pyramid shape, a conical shape, and a semisphere shape.

7. The apparatus according to claim 1, wherein
the second projecting portions are arranged at almost equal intervals.

8. The apparatus according to claim 5, wherein
the second projecting portions are arranged at almost equal intervals.

9. The apparatus according to claim 1, wherein
the second projecting portion is formed in an annular ridge shape.

10. A vapor-phase growing method using a vapor-phase growing apparatus including:
a chamber which forms a space for performing vapor-phase growth;
a substrate support table arranged in the chamber;
a gas supply unit which supplies a process gas to form a film by the vapor-phase growth into the chamber; and
a gas discharge unit which discharges the process gas after film formation from the chamber, wherein
the substrate support table includes a disk-like member having a recessed portion formed at a center thereof or a ring-like member formed by forming a recessed portion at the center of the substrate support table and forming an opening at a bottom center of the substrate support table,
a first projecting portion formed on an inner circumference wall surface of the substrate support table to project from the inner circumference wall surface to the inside, and
a second projecting portion formed upwardly from a bottom surface of the recessed portion of the substrate support table, comprising:
placing a substrate on the substrate support table,
supplying the process gas from the gas supply unit, and
forming a vapor-phase growing film on the substrate.

11. The method according to claim 10, wherein
the first projecting portion is annularly arranged along the inner circumference wall surface.

12. The method according to claim 10, wherein
the first projecting portion has a triangular section.

13. The method according to claim 11, wherein
the first projecting portion has a triangular section.

14. The method according to claim 10, wherein
the second projecting portions are arranged at equal intervals.

15. The method according to claim 13, wherein
the second projecting portions are arranged at equal intervals.

16. The method according to claim 10, wherein
when a thickness of the substrate is represented by t, and when a height of a position of a distal end portion of the first projecting portion with reference to the substrate bottom surface is represented by X₁, 0.3t≦X₁≦0.5t is satisfied.

17. The method according to claim 15, wherein
when a thickness of the substrate is represented by t, and when a height of a position of a distal end portion of the first projecting portion with reference to the substrate bottom surface is represented by X₁, 0.3t−X₁≦0.5t is satisfied.
